(19) United States
(12) Patent Application Publication
(10) Pub. No.: US 2010/0047968 A1
(43) Pub. Date: Feb. 25, 2010

(54) ADHESIVE SHEET FOR PRODUCING A SEMICONDUCTOR DEVICE, AND A METHOD FOR PRODUCING A SEMICONDUCTOR DEVICE USING THE SAME

(76) Inventors: Yasuhiro Amano, Osaka (JP); Yoshio Terada, Osaka (JP); Naohide Takamoto, Osaka (JP)

Correspondence Address: KNOBBE MARTENS OLSON & BEAR LLP, 2040 MAIN STREET, FOURTEENTH FLOOR, IRVINE, CA, 92614, US

(21) Appl. No.: 12/519,510

(22) PCT Filed: Dec. 13, 2007
(86) PCT No.: PCT/JP2007/074009

§ 371 Date: Jun. 16, 2009

(30) Foreign Application Priority Data
Dec. 18, 2006 (JP) 2006-340259

(51) Int. Cl. H01L 21/78; C08K 3/36; B32B 5/16

(52) U.S. Cl. 438/110; 524/442; 428/331; 257/E21.567; 257/E21.599

(57) ABSTRACT

The present invention relates to an adhesive sheet for producing a semiconductor device, which is used when a semiconductor element is caused to adhere onto an adherend and the semiconductor element is wire-bonded, in which a lipophilic lamellar clay mineral is contained.

### TECHNICAL FIELD

The present invention relates to an adhesive sheet, for producing a semiconductor device, used when a semiconductor element is caused to adhere onto an adherend and then the semiconductor element is wire-bonded, and a method for producing a semiconductor device using the same.

### BACKGROUND ART

In order to meet the request that semiconductor devices are made finer and caused to have higher functions, the wiring width of power supply lines arranged in the entire area of the main faces of their semiconductor chips (semiconductor elements) or the interval between signal lines arranged therein has been becoming narrower.

For this reason, the impedance thereof increases or signals between signal lines of different nodes interfere with each other so as to cause hindrance to the exhibition of sufficient performances for the operation speed of the semiconductor chips, the margin of the operating voltage thereof, the resistance thereof against damage by electrostatic discharge, and others. In order to solve these problems, for example, in JP-A-55-111151 and JP-A-2002-261233, package structures wherein semiconductor elements are laminated are suggested.

As a material used to stick semiconductor elements to a substrate or the like, the following examples are suggested: an example wherein a thermosetting paste resin is used (see, for example, JP-A-2002-179769); and examples wherein an adhesive sheet composed of a thermoplastic resin and a thermosetting resin is used (see, for example, JP-A-2000-104040 and JP-A-2002-261233).

In conventional processes for producing a semiconductor device, an adhesive sheet or an adhesive is used to adhere semiconductor elements onto a substrate, a lead frame or semiconductor elements. The adhesion is performed by attaching the semiconductor elements to the substrate or the like under pressure (die attaching) and then curing the adhesive sheet or the like in a heating step. In this production method, wire bonding is performed in order to electrically bond the semiconductor element and the substrate each other, and then the semiconductor element is molded with a sealing resin and post-cured to seal the element with the sealing resin.

However, when the wire bonding is performed, the semiconductor elements on the substrate or the like are shifted by ultrasonic vibration or heating. Conventionally, therefore, it is necessary to perform a heating step before the wire bonding so as to heat and cure the thermosetting paste resin or thermosetting adhesive sheet, thereby sticking/fixing the semiconductor elements so as not to be shifted.

An adhesive sheet made of a thermoplastic resin or an adhesive sheet composed of a thermosetting resin and a thermoplastic resin is required to undergo a heating step after die attaching and before wire bonding in order to ensure adhesive force thereof onto an object which is to be stuck with the sheet, or improve the wettability thereof onto the object.

However, there is caused a problem that volatile gas is generated from the adhesive sheet or the like by the heating thereof which is performed before wire bonding. The volatile gas contaminates bonding pads. Thus, no wire bonding will be able to be carried out in many cases.

By heating and curing the adhesive sheet or the like, curing, shrinking or the like is caused in the adhesive sheet or the like. With this, stress is generated so as to result in a problem that a warpage is generated in the lead frame or the substrate stuck on the sheet (as well as the semiconductor elements). Additionally, a problem that a crack is generated in the semiconductor elements on the basis of the stress is caused in a wire bonding step.

As semiconductor elements have been becoming thinner and smaller in recent years, the thickness of the semiconductor elements has been made thinner below 200 μm, which is a conventional thickness, even 100 μm or less. When a semiconductor element having a thickness of 100 μm or less is used to perform die-attachment, the semiconductor element may be warped. Thus, a gap may be generated between the semiconductor and the adherend after the die-attachment. Moreover, as chips are laminated so as to give a larger layer-number and the number of pins therein is made larger, thermal history in a wire bonding step therefor becomes longer. As a result, the curing of the adhesive sheet is advanced so that the fluidity and the embeddable property are declined so that a gap is easily generated between the semiconductor elements and the adherend. When a semiconductor device is produced in the state that the gap is left as it is, there is caused a problem that the reliability thereof is declined.

### DISCLOSURE OF THE INVENTION

### Problems to be Solved by the Invention

In light of the problems, the present invention has been made, and an object thereof is to provide a method for producing a semiconductor device capable of producing a highly reliable semiconductor device with an improvement in heat resistance without changing a conventional producing process, an adhesive sheet for using this process, and a semiconductor device yielded by this process.

### Means for Solving the Problems

In order to solve the above-mentioned problems, the present inventors have made eager investigations on an adhesive sheet for producing a semiconductor device, and a method for producing a semiconductor device using the same. As a result, the inventors find out that the above-mentioned object can be attained by adopting a configuration that will be described below, to complete the invention.

That is, in order to solve the above-mentioned problems, the present invention relates to an adhesive sheet for producing a semiconductor device, which is used when a semiconductor element is caused to adhere onto an adherend and the semiconductor element is wire-bonded, in which a lipophilic lamellar clay mineral is contained.

The adhesive sheet of the invention is constructed to contain a lamellar clay mineral. The lamellar clay mineral is dispersed in such a manner that the lamination direction thereof is substantially consistent with the direction perpendicular to the in-plane direction of the adhesive sheet. The lamellar clay mineral reinforces the mechanical strength of the adhesive sheet in the in-plane direction; therefore, in the adhesive sheet according to the invention, shearing deformation is not generated in an adhesive face between the adhesive sheet and a semiconductor element plus an adherend by ultrasonic vibration when the element is wire-bonded. Furthermore, the heat resistance of the adhesive sheet itself can be improved by the matter that the sheet contains the lamellar clay mineral; therefore, the generation of shearing deformation resulting from heating can also be restrained. As a result, adhesive sheets excellent in wire bonding property are obtained.

In the meantime, about the adhesive sheet of the invention, the elasticity in the direction perpendicular to the in-plane direction thereof is substantially equal to that of conventional adhesive sheets. Thus, the cushion property in the same direction is not damaged. This matter makes it possible to prevent the generation of a gap in an adhesive face between a semiconductor element and an adherend.

The reason why a lipophilic substance is adopted as the lamellar clay mineral is that the substance is excellent in compatibility with the adhesive composition that constitutes the adhesive sheet so that the lipophilic substance can gain a good dispersibility.

In the above-described constitution, it is also preferable that the content of the lamellar clay mineral ranges from 0.1 to 40 parts by weight for 100 parts by weight of an adhesive composition that constitutes the adhesive sheet. This makes it possible to improve the heat resistance without damaging the adhesion property of the adhesive sheet.

It is also preferable that the adhesive sheet has a shearing adhesive force of 0.2 to 2 MPa to the adherend under a condition of 175° C. temperature. This makes it possible to restrain shearing deformation still further from being generated in the adhesive face between the adhesive sheet and the adherend by ultrasonic vibration or heating at the time of wire bonding.

It is also preferable that the adhesive sheet has a tensile storage elasticity of 1×10⁴ Pa or more at 120° C. before the sheet is cured, and has a tensile storage elasticity of 50 MPa or less at 200° C. after the sheet is cured.

In a case where the adhesive sheet is constructed to have storage elastic modulus as in the above-mentioned structure, even under the condition of a high temperature the adhesive sheet exhibits such a heat resistance that the sheet can sufficiently endure the condition at each of times before and after the sheet is cured. Thus, the adhesive sheet is restrained from softening or flowing. As a result, stable wire bonding can be attained. Thus, semiconductor devices can be produced while a decline in the yield can be still further restrained.

In the above-described constitution, it is also preferable that the adhesive composition comprises a thermoplastic resin.

In the above-described constitution, it is also preferable that the adhesive composition comprises a thermoplastic resin and a thermosetting resin.

It is also preferred to use, as the thermosetting resin, epoxy resin and/or phenol resin and use, as the thermoplastic resin, acrylic resin. These resins are high in heat resistance since the amount of ionic impurities therein is small. As a result, the reliability of the semiconductor element(s) can be certainly kept.

In addition, it is preferably that a crosslinking agent is added to the adhesive sheet.

It is preferably that the lipophilic lamellar clay mineral is a lamellar silicate. The lamellar silicate is excellent in practicability. When this is incorporated into the adhesive sheet, the orientation of the lamellar silicate in the in-plane direction is made good and further the dispersibility in the adhesive sheet is also improved. As a result, the generation of shearing deformation can be still further decreased at the time of wire bonding.

The use of the lamellar silicate also makes it possible to make the heat resistance of the adhesive sheet even better. For this reason, even when the adhesive sheet undergoes thermal history for a long period in the wire bonding step or the like, the adhesive sheet can be kept in a state that the sheet is temporarily bonded without being completely bonded.

In order to solve the above-mentioned problems, the present invention relates to a method for producing a semiconductor device includes a temporarily-bonding step of bonding a semiconductor element temporarily onto an adherend interposed an adhesive sheet for producing the semiconductor device therebetween containing a lipophilic lamellar clay mineral, a wire bonding step of wire-bonding the semiconductor element, a sealing step of resin-sealing the semiconductor element with a sealing resin, and a cutting step of cutting the sealed structure into individual semiconductor elements.

According to the producing process of the invention, a sheet containing a lamellar clay mineral is used as the adhesive sheet for fixing a semiconductor element to an adherend; therefore, even when the semiconductor element is shifted to a wire bonding step without performing any heating step of the adhesive sheet, no shearing deformation is generated in the adhesive face between the adhesive sheet and the semiconductor element plus the adherend by ultrasonic vibration or heating in the wire bonding step. For this reason, the wire bonding can be attained while a decline in the yield is restrained.

Moreover, the adhesive sheet containing the lamellar clay mineral is also excellent in heat resistance; therefore, even when the sheet undergoes thermal history for a long period, for example, in a wire bonding step, the curing of the adhesive sheet is restrained from advancing. As a result, a deterioration in the fluidity and the embeddable property of the adhesive sheet is suppressed. Thus, the generation of a gap can be prevented between the adhesive sheet and the semiconductor element plus the adherend.

In conventional producing processes, an adhesive sheet is heated before their wire bonding step. By the heating, a volatile gas is generated from the adhesive sheet so that the bonding pads may be polluted. In the invention, however, such a step is not required. Thus, the bonding pads are never polluted. Moreover, the step number is decreased so that the yield can be improved. Furthermore, the step of heating the adhesive sheet is omitted, so that the substrate or the like is not warped and the semiconductor element is not cracked. As a result, the semiconductor element can be made still thinner.

In the above-described method, it is also preferable that the adherend is a substrate, a lead frame, or a semiconductor element.

It is also preferable that the method for producing a semiconductor device includes the sealing step of sealing the semiconductor element with the sealing resin, and an post-curing step of post-curing the sealing resin, in which in at least one of the sealing step or the after-curing step, the sealing resin is heated so as to be cured, and further the semiconductor element and the adherend are bonded to each other interposed the adhesive sheet therebetween. This makes it possible to attain the bonding through the adhesive sheet at the same time of curing the sealing resin in at least one of the sealing step or the post-curing step. As a result, the producing step can be made simple.

In the above-described method, it is also preferable that the wire bonding step is performed at a temperature ranging from 80 to 250° C. When the wire bonding step is performed in this temperature range, the semiconductor element and the adherend or the like can be prevented from being completely bonded to each other through the adhesive sheet.

In the above-described method, it is also preferable that the lipophilic lamellar clay mineral is a lamellar silicate. The lamellar silicate is excellent in practicability. When this is incorporated into the adhesive sheet, the orientation of the lamellar silicate in the in-plane direction is made good and further the dispersibility in the adhesive sheet is also improved. As a result, the generation of shearing deformation can be still further decreased at the time of wire bonding.

The use of the lamellar silicate also makes it possible to improve the heat resistance of the adhesive sheet. For this reason, even when the adhesive sheet undergoes thermal history for a long period in a wire bonding step or the like, the adhesive sheet can be kept in a state that the sheet is temporarily bonded without being completely bonded. Furthermore, even in a case where a semiconductor element is warped when wire-bonded, the semiconductor element is in a state that the element is temporarily bonded to the adherend; therefore, the warp of the semiconductor element can be decreased by pressure applied thereto in the step of sealing the element. As a result, the semiconductor element can finally be bonded and fixed onto the adherend without generating any gap.

The same action and effects as described above are produced also in the case of laminating, onto the above-mentioned semiconductor element, one or more semiconductor elements so as to interpose the adhesive sheet therebetween or in the case of laminating a spacer between the above-mentioned semiconductor element and a semiconductor element so as to interpose the adhesive sheet therebetween as the need arises. Additionally, the above-mentioned simplification of the producing process makes it possible to improve the production efficiency further in three-dimensionally packaging of plural semiconductor elements, or the like.

### BRIEF DESCRIPTION OF THE DRAWINGS

FIG. 1 are each a sectional view which schematically illustrates an adhesive sheet, for producing a semiconductor device, according to the Embodiment 1 of the invention.

FIG. 2 is process chart illustrating a process for producing a semiconductor device according to the Embodiment 1 of the present invention;

FIG. 3 is process chart illustrating a process for producing a semiconductor device according to the Embodiment 2 of the present invention;

FIG. 4 is process chart illustrating a process for producing a semiconductor device according to the Embodiment 3 of the present invention;

FIG. 5 is process chart illustrating a process for producing a semiconductor device according to the Embodiment 4 of the present invention;

FIG. 6 is process chart illustrating a process for producing a semiconductor device according to the Embodiment 5 of the present invention;

FIG. 7 is process chart illustrating a process for producing a semiconductor device according to the Embodiment 6 of the present invention;

FIG. 8 is a sectional view schematically illustrating a semiconductor device obtained by the process for producing the semiconductor device according to the Embodiment 6 of the present invention; and

FIG. 9 is process chart illustrating a process for producing a semiconductor device according to the Embodiment 7 of the present invention.

### DESCRIPTION OF NOTATIONS

10 adhesive sheet
10a core material
10b adhesive layer
11 substrate (adherend)
12 adhesive sheet
13′ semiconductor wafer
13 semiconductor element
14 adhesive sheet
15 sealing resin
16 bonding wire
21 spacer
31 adhesive sheet
32 semiconductor element
33 dicing tape
41 adhesive sheet
42 core material

### BEST MODE FOR CARRYING OUT THE INVENTION

### Embodiment 1

First, the adhesive sheet according to the invention for producing a semiconductor device will be described hereinafter.

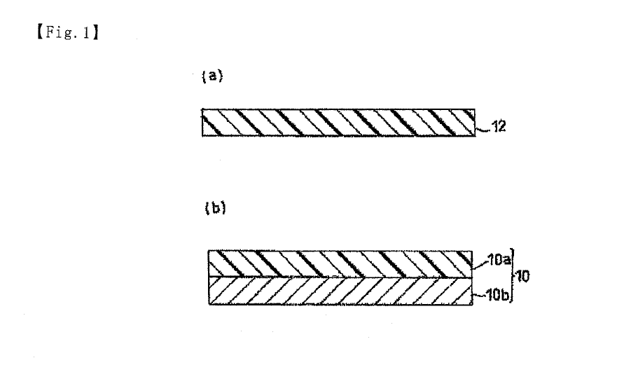

The adhesive sheet according to the invention is not particularly limited in the structure thereof as far as the adhesive sheet contains a lamellar clay mineral. Examples thereof are as follows: as illustrated in FIG. 1(a), an adhesive sheet 12 made only of a single adhesive layer; as illustrated in FIG. 1(b), an adhesive sheet 10 wherein an adhesive layer 10b is laminated on a single surface of a core material 10a; and an adhesive sheet having a multilayered structure wherein adhesive layers are formed on both surfaces thereof, respectively.

Examples of the core material include films (such as a polyimide film, a polyester film, a polyethylene terephthalate film, a polyethylene naphthalate film, and a polycarbonate film); resin substrates each reinforced with glass fiber or plastic nonwoven fiber; silicon substrates; and glass substrates. Of these core materials, a preferably usable material, which depends on a combination with the constituent material of the adhesive layer, is, for example, a material made of a crosslinked thermoplastic resin. This is because the use of the crosslinked resin causes a fall in the fluidity of the core material. It is allowable to use a material of a type wherein an adhesive sheet is integrated with a dicing sheet.

The lamellar clay mineral is not particularly limited, and examples thereof include lamellar silicates, and boron nitride. Of these lamellar clay minerals, lamellar silicates are each preferred from the viewpoint of the orientation and dispersibility thereof in the adhesive sheet. The use of the lamellar silicate makes it possible to make the orientation of the lamellar silicate contained in the adhesive sheet uniform and improve the mechanical strength in a specified direction. Moreover, the dispersibility of the lamellar silicate can also be made uniform. For these reasons, the generation of shearing deformation can be uniformly decreased in the plane of the adhesive sheet.

The lamellar silicate is not particularly limited, and examples thereof include saponite, sauconite, stevensite, hectorite, margarite, talc, golden mica, chrysotile, chlorite, vermiculite, kaolinite, white mica, xanthophyllite, dickite, nacrite, pyrophyllite, montmorillonite, beidellite, nontronite, tetrasi-licic mica, sodium tainiolite, antigorite, and halloysite. These may be used alone or in combination of two or more thereof. The lamellar silicate may a natural substance or a synthesized substance.

The average length of the long diameters (or major axes) of the lamellar clay mineral ranges preferably from 0.01 to 100 μm, more preferably from 0.05 to 10 μm. When the average length is set into the numerical range, the lamellar clay mineral can be dispersed in such a manner that the lamination direction of the mineral is inconsistent with the in-plane direction of the adhesive sheet. The aspect ratio (ratio of the long diameter to the short diameter) of the lamellar clay mineral ranges preferably from 20 to 500, more preferably from 50 to 200. The setting of the ratio into the numerical range also makes it possible to disperse the lamellar clay mineral in such a manner that the lamination direction of the mineral is inconsistent with the in-plane direction of the adhesive sheet. The average length of the lamellar clay mineral is a value obtained by measurement with an atomic force microscope. The aspect ratio of the lamellar clay mineral is also a value obtained by measurement with an atomic force microscope.

The content of the lamellar clay mineral is not particularly limited, and is set in such a manner that heat resistance and release effect are obtained correspondingly to the adherend, which will be described later. Specifically, the content ranges preferably from 0.1 to 40 parts by weight for 100 parts by weight of the adhesive composition that constitutes the adhesive sheet, more preferably from 10 to 30 parts by weight therefor. When the content is set into the numerical range, the adhesive property of the adhesive sheet is made good and further the heat resistance can also be improved. If the content is more than 40 parts by weight, the cohesive force becomes too high so that the peelability is declined after the sheet is heated. Thus, the adhesive property of the adhesive is lost so that the picking-up performance may be declined. On the other hand, if the content is less than 0.1 part by weight, the heat resistance becomes insufficient so that the resistance against thermal history for a long period falls. Thus, the wire bonding property may be declined. The peel strength of the adhesive sheet is desirably adjusted on the basis of the content of the lamellar clay mineral.

In the state that the adhesive sheet (in a case where the adhesive sheet is a sheet wherein an adhesive layer is laminated on a core material, the adhesive layer) is bonded to an adherend and the resultant is heated up to 175° C., the shearing adhesive force is preferably from 0.2 to 2 MPa, more preferably from 0.4 MPa to 1.6 MPa. When the shearing adhesive force of the adhesive sheet is set to 0.2 MPa or more, the following is made possible even if the sheet undergoes a wire bonding step, which will be described later: a further restraint of the generation of shearing deformation in an adhesive face between the adhesive sheet and a semiconductor element plus an adherend by ultrasonic vibration or heating in this step. In other words, a semiconductor is restrained from being shifted by ultrasonic vibration when wired-bonded. In this way, a fall in the success probability of the wire bonding is prevented. The semiconductor element can also be prevented from flowing by pressure in the sealing step thereof. If the shearing adhesive force is more than 2 MPa or more, the adhesive force is too large so that chips of the semiconductor are not easily picked up in the picking-up step thereof. The shearing adhesive force can be adjusted by adjusting the mixed amount of the epoxy resin and the phenol resin appropriately in the organic resin composition in the adhesive sheet.

The adhesive sheet (in a case where the adhesive sheet is a sheet wherein an adhesive layer is laminated on a core material, the adhesive layer) preferably has elasticity in some measure at least in the direction perpendicular to the in-plane direction from the viewpoint of the adhesive function of the sheet. In the meantime, in a case where the adhesive sheet has elasticity excessively as a whole, sufficient fixation of a lead frame to which the adhesive sheet is attached is hindered by elastic force of the adhesive sheet even when bonding wires are connected at the time of wire bonding. As a result, compression energy based on pressure-application is relieved so that a bonding failure is generated. In the wire bonding step, the bonding is performed under a high temperature condition of about 150° C. to 200° C. temperature. It is therefore preferred that the tensile storage elasticity at 120° C. before the adhesive sheet is cured is 1×10⁴ Pa or more, more preferably from 0.1 to 20 MPa. If the tensile storage elasticity is less than 1×10⁴ Pa, the adhesive sheet melted when the semiconductor is diced is bonded to, for example, chips of the semiconductor. As a result, the chips may not be picked up with ease. The tensile storage elasticity at 200° C. after the adhesive sheet is cured is preferably 50 MPa or less, more preferably from 0.5 to 40 MPa. If the elasticity is more than 50 MPa, the embeddable property of the adhesive sheet to an uneven face may be declined at the time of molding after the wire bonding. When the elasticity is set to 0.5 MPa or more, stable wire connection can be attained in a semiconductor device characterized by having a leadless structure. The tensile storage elasticity can be adjusted by adjusting the added amount of the lamellar silicate or an inorganic filler, which will be described later, appropriately. A method for measuring the tensile storage elasticity will be described later.

The above-mentioned adhesive layer is a layer having an adhesive function. The constituent material thereof may be a material wherein a thermoplastic resin and a thermosetting resistance are used together. A thermoplastic resin alone may be used.

Examples of the thermoplastic resin include natural rubber, butyl rubber, isoprene rubber, chloroprene rubber, ethylene/vinyl acetate copolymer, ethylene/acrylic acid copolymer, ethylene/acrylic ester copolymer, polybutadiene resin, polycarbonate resin, thermoplastic polyimide resin, polyamide resins such as 6-nylon and 6,6-nylon, phenoxy resin, acrylic resin, saturated polyester resins such as PET and PBT, polyamideimide resin, and fluorine-contained resin. These thermoplastic resins may be used alone or in combination of two or more thereof. Of these thermoplastic resins, acrylic resin is particularly preferable since the resin contains ionic impurities in only a small amount and has a high heat resistance so as to make it possible to ensure the reliability of the semiconductor element.

The acrylic resin is not limited to any especial kind, and may be, for example, a polymer comprising, as a component or components, one or more esters of acrylic acid or methacrylic acid having a linear or branched alkyl group having 30 or less carbon atoms, in particular, 4 to 18 carbon atoms. Examples of the alkyl group include methyl, ethyl, propyl, isopropyl, n-butyl, t-butyl, isobutyl, amyl, isoamyl, hexyl, heptyl, cyclohexyl, 2-ethylhexyl, octyl, isooctyl, nonyl, isononyl, decyl, isodecyl, undecyl, lauryl, tridecyl, tetradecyl, stearyl, octadecyl, and dodecyl groups.

A different monomer which constitutes the above-mentioned polymer is not limited to any especial kind, and examples thereof include carboxyl-containing monomers such as acrylic acid, methacrylic acid, carboxyethyl acrylate, carboxypentyl acrylate, itaconic acid, maleic acid, fumaric acid, and crotonic acid; acid anhydride monomers such as maleic anhydride and itaconic anhydride; hydroxyl-containing monomers such as 2-hydroxyethyl (meth)acrylate, 2-hydroxypropyl (meth)acrylate, 4-hydroxybutyl (meth)acrylate, 6-hydroxyhexyl (meth)acrylate, 8-hydroxyoctyl (meth)acrylate, 10-hydroxydecyl (meth)acrylate, 12-hydroxylauryl (meth)acrylate, and (4-hydroxymethylcyclohexyl)methylacrylate; monomers which contain a sulfonic acid group, such as styrenesulfonic acid, allylsulfonic acid, 2-(meth)acrylamide-2-methylpropanesulfonic acid, (meth)acrylamidepropane sulfonic acid, sulfopropyl (meth)acrylate, and (meth)acryloyloxynaphthalenesulfonic acid; and monomers which contain a phosphoric acid group, such as 2-hydroxyethylacryloyl phosphate.

Examples of the above-mentioned thermosetting resin include phenol resin, amino resin, unsaturated polyester resin, epoxy resin, polyurethane resin, silicone resin, and thermosetting polyimide resin. These resins may be used alone or in combination of two or more thereof. Particularly preferable is epoxy resin, which contains ionic impurities which corrode semiconductor elements in only a small amount. As the curing agent of the epoxy resin, phenol resin is preferable.

The epoxy resin may be any epoxy resin that is ordinarily used as an adhesive composition. Examples thereof include bifunctional or polyfunctional epoxy resins such as bisphenol A type, bisphenol F type, bisphenol S type, brominatedbisphenol A type, hydrogenated bisphenol A type, bisphenol AF type, biphenyl type, naphthalene type, fluorene type, phenol Novolak type, orthocresol Novolak type, tris-hydroxyphenylmethane type, and tetraphenylolethane type epoxy resins; hydantoin type epoxy resins; tris-glycicylisocyanurate type epoxy resins; and glycidylamine type epoxy resins. These may be used alone or in combination of two or more thereof. Among these epoxy resins, particularly preferable are Novolak type epoxy resin, biphenyl type epoxy resin, tris-hydroxyphenylmethane type epoxy resin, and tetraphenylolethane type epoxy resin, since these epoxy resins are rich in reactivity with phenol resin as an agent for curing the epoxy resin and are superior in heat resistance and so on.

The phenol resin is a resin acting as a curing agent for the epoxy resin. Examples thereof include Novolak type phenol resins such as phenol Novolak resin, phenol aralkyl resin, cresol Novolak resin, tert-butylphenol Novolak resin and nonylphenol Novolak resin; resol type phenol resins; and polyoxystyrenes such as poly (p-oxystyrene). These may be used alone or in combination of two or more thereof. Among these phenol resins, phenol Novolak resin and phenol aralkyl resin are particularly preferable, since the connection reliability of the semiconductor device can be improved.

About the blend ratio between the epoxy resin and the phenol resin, for example, the phenol resin is blended with the epoxy resin in such a manner that the hydroxyl groups in the phenol resin is preferably from 0.5 to 2.0 equivalents, more preferably from 0.8 to 1.2 equivalents per equivalent of the epoxy groups in the epoxy resin component. If the blend ratio between the two is out of the range, curing reaction therebetween does not advance sufficiently so that properties of the cured epoxy resin easily deteriorate.

In the present invention, an adhesive sheet comprising the epoxy resin, the phenol resin, and an acrylic resin is particularly preferable. Since these resins contain ionic impurities in only a small amount and have high heat resistance, the reliability of the semiconductor element can be ensured. About the blend ratio in this case, the amount of the mixture of the epoxy resin and the phenol resin is from 10 to 200 parts by weight for 100 parts by weight of the acrylic resin component.

In order to crosslink the adhesive sheet 12 of the present invention to some extent in advance, it is preferable to add, as a crosslinking agent, a polyfunctional compound which reacts with functional groups of molecular chain terminals of the above-mentioned polymer to the materials used when the sheet 12 is produced. In this way, the adhesive property of the sheet at high temperatures is improved so as to improve the heat resistance.

The crosslinking agent may be one known in the prior art. Particularly preferable are polyisocyanate compounds, such as tolylene diisocyanate, diphenylmethane diisocyanate, p-phenylene diisocyanate, 1,5-naphthalene diisocyanate, and adducts of polyhydric alcohol and diisocyanate.

The amount of the crosslinking agent to be added is preferably set to 0.05 to 7 parts by weight for 100 parts by weight of the above-mentioned polymer. If the amount of the crosslinking agent to be added is more than 7 parts by weight, the adhesive force is unfavorably lowered. On the other hand, if the adding amount is less than 0.05 part by weight, the cohesive force is unfavorably insufficient. A different polyfunctional compound, such as an epoxy resin, together with the polyisocyanate compound may be incorporated if necessary.

An inorganic filler may be appropriately incorporated into the adhesive sheet 12 of the present invention in accordance with the use purpose thereof. The incorporation of the inorganic filler makes it possible to confer electric conductance to the sheet, improve the thermal conductivity thereof, and adjust the elasticity. Examples of the inorganic fillers include various inorganic powders made of the following: a ceramic such as silica, clay, plaster, calcium carbonate, barium sulfate, aluminum oxide, beryllium oxide, silicon carbide or silicon nitride; a metal such as aluminum, copper, silver, gold, nickel, chromium, lead, tin, zinc, palladium or solder, or an alloy thereof; and carbon. These may be used alone or in combination of two or more thereof. Among these, silica, in particular fused silica is preferably used. The average particle size of the inorganic filler is preferably from 0.1 to 80 μm.

The amount of the inorganic filler to be incorporated is preferably set into the range of 0 to 80 parts by weight (more preferably, 0 to 70 parts by weight) for 100 parts by weight of the organic resin components.

If necessary, other additives besides the inorganic filler may be incorporated into the adhesive sheet 12 of the present invention. Examples thereof include a flame retardant, a silane coupling agent, and an ion trapping agent.

Examples of the flame retardant include antimony trioxide, antimony pentaoxide, and brominated epoxy resin. These may be used alone or in combination of two or more thereof.

Examples of the silane coupling agent include β-(3,4-epoxycyclohexyl)ethyltrimethoxysilane, γ-glycidoxypropyltrimethoxysilane, and γ-glycidoxypropylmethyldiethoxysilane. These may be used alone or in combination of two or more thereof.

Examples of the ion trapping agent include hydrotalcite and bismuth hydroxide. These may be used alone or in combination of two or more thereof.

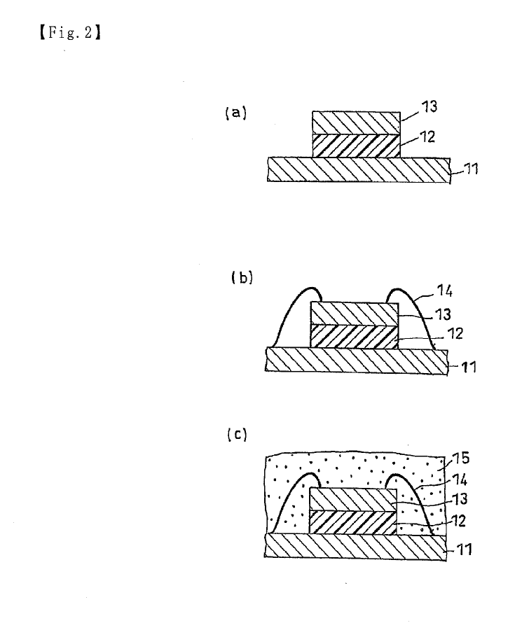

With reference to FIG. 2, the following will describe a method for producing a semiconductor device using the adhesive sheet 12.

The method for producing a semiconductor device according to the present embodiment includes a temporarily-bonding step of bonding a semiconductor element 13 onto a substrate or lead frame (adherend, which will be referred to merely as a substrate or the like) 11 through the adhesive sheet 12; and a wire bonding step of wire-bonding the semiconductor element 13; and a sealing step of sealing the semiconductor element 13 with a sealing resin 15.

As illustrated in FIG. 2(a), the pre-setting step is a step of pre-setting the semiconductor element 13 through the adhesive sheet 12 onto the substrate 11 or the like. The method for pre-setting the semiconductor substrate 13 onto the substrate 11 or the like may be, for example, a method of laminating the adhesive sheet 12 onto the substrate 11 or the like and subsequently laminating and pre-setting the semiconductor element 13 on the adhesive sheet 12 in such a manner that the wire bonding face of the semiconductor element 13 is directed upwards. The semiconductor element 13 on which the adhesive sheet 12 is beforehand pre-set may be pre-set onto the substrate 11 or the like.

In the invention, the thickness of the semiconductor element 13 is not particularly limited. The thickness is usually 200 μm or less. The invention can be applied to, for example, a semiconductor element having a thickness of 100 μm or less, and further applied to a semiconductor element having a thickness of 25 to 50 μm. When the semiconductor 13, which is made thin, is temporarily bonded to the substrate or the like 11, the semiconductor element 13 may be warped in a concave or convex form. As a result, a gap is generated between the element and the substrate or the like 11 to result in an inconvenience that a highly reliable semiconductor device cannot be obtained. However, in the invention, the sealing step, which will be described later, is performed, thereby making it possible to bond the semiconductor element 13 onto the substrate or the like 11 and further stuff the gap. Details thereof will be described later.

The substrate may be any substrate known in the prior art. The lead frame may be a metal lead frame such as a Cu lead frame or a 42-alloy lead frame; or an organic substrate made of glass epoxy resin, BT (bismaleimide-triazine), polyimide or the like. In the present invention, however, the substrate is not limited to these substrates, and may be a circuit substrate that can be used in the state that a semiconductor element is mounted on the substrate itself and is electrically connected thereto.

The wire bonding step is a step of electrically connecting the tips of terminal portions (inner leads) of the substrate 11 or the like to electrode pads (not illustrated) on the semiconductor element 13 through bonding wires 16 (see FIG. 2(b)). As the bonding wires 14, for example, gold wires, aluminum wires or copper wires are used. When the wire bonding is performed, the bonding temperature is indispensably from 80 to 250° C., preferably from 80 to 220° C. The heating time is from several seconds to several minutes. The wire-connection is attained by use of both of vibration energy based on ultrasonic waves and compression energy based on the application of pressure in the state that the workpiece is heated to a temperature in the above-mentioned range.

The present step is carried out without performing any fixation through the adhesive sheet 12. In the course of the step, the semiconductor element 13 and the substrate or the like 11 are not bonded to each other through the adhesive sheet 12. The shearing adhesive force of the adhesive sheet 12 is preferably 0.2 MPa or more even when the temperature is in the range of 80 to 250° C. If the shearing adhesive force is less than 0.2 MPa in the temperature range, the semiconductor element is shifted by ultrasonic vibration when wire-bonded. Thus, the wire bonding cannot be attained so that the yield may be declined.

The above-mentioned sealing step is a step of sealing the semiconductor element 13 with a sealing resin 15 (see FIG. 2(c)), and is performed to protect the semiconductor element 13 and the bonding wires 16 mounted on the substrate 11 or the like. The present step is performed by molding the sealing resin with a mold or die. The sealing resin 15 may be, for example, an epoxy resin. The heating for the resin-sealing is performed usually at 175° C. for 60 to 90 seconds. In the this invention, however, the heating is not limited to this, and may be performed, for example at 150 to 200° C. for several minutes. In the present step, the application of pressure may be performed at the time of the resin-sealing. In this case, the pressure to be applied is preferably from 1 to 15 MPa, more preferably from 3 to 10 MPa. When the pressure in the range is applied, the semiconductor element 13 and the substrate or the like 11 can be bonded to each other interposed the adhesive sheet 12 therebetween and further a gap present therebetween can be stuffed. As a result, the bonding through the adhesive sheet 12 can be attained in the present step even if an after-curing step, which will be descried later, is not performed. Thus, the pressure-application can contribute to a decrease in the number of the producing steps and a reduction in the period for the semiconductor-device-production. The bond area where the substrate or the like 11 and to the semiconductor element 13 are bonded to each other is preferably 90% or more, more preferably 95% or more. If the bond area is less than 90%, an inconvenience about humidity-resistant reliability may be generated. The bond area denotes an area where the semiconductor element 13 and the substrate or the like 11 are bonded to each other interposed the adhesive sheet 12 therebetween, and does not contain any area where the adhesive sheet 12 is bonded only to any one of the two.

In the invention, an after-curing step of after-curing the sealing resin 15 may be performed after the sealing step. In the step, the sealing resin 15 that is not sufficiently cured in the sealing step is completely cured. The heating temperature in the step, which is varied in accordance with the kind of the sealing resin, ranges, for example, from 150 to 200° C., and the heating period is from about 0.5 to 8 hours.

### Embodiment 2

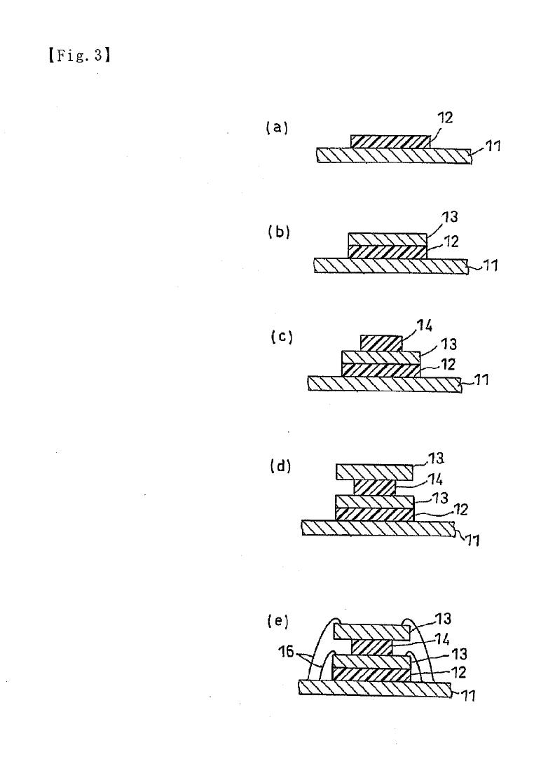

A process for producing a semiconductor device according to embodiment 2 is described with reference to FIG. 3, which are process charts for explaining this process.

The semiconductor device according to the present embodiment is different from the semiconductor device according to the above-mentioned embodiment 1 in that plural semiconductor elements are laminated to be three-dimensionally mounted. More specifically, the present embodiment comprises the step of laminating, on a semiconductor element, another semiconductor element through the adhesive sheet as described above, which is different from the embodiment 1.

First, as illustrated in FIG. 3(a), at least one adhesive sheet 12, which is cut into a given size, is pre-set onto a substrate 11 or the like, which is an object on which the sheet 12 is to be set. Next, a semiconductor element 13 is pre-set onto the adhesive sheet 12 so that the wire bonding face thereof is directed upwards (see FIG. 3(b)). Furthermore, an adhesive sheet 14 is pre-set onto the semiconductor element 13 to avoid electrode pad portions of the element 13 (see FIG. 3(c)). Another semiconductor element 13 is then formed on the adhesive sheet 14 so that the wire bonding face thereof is directed upwards (see FIG. 3(d)).

Next, as illustrated in FIG. 3(e), a wire bonding step is carried out without performing any heating step, thereby electrically connecting electrode pads of the semiconductor elements 13 to the substrate 11 or the like through bonding wires 16.

Next, a sealing step of sealing the semiconductor elements 13 with a sealing resin is performed to cure the sealing resin and further to stick/fix the substrate 11 or the like onto one of the semiconductors 13 and stick/fix the semiconductor elements 13 each other through the adhesive sheets 12 and 14. After the sealing step, a post-curing step may be performed.

According to the present embodiment, about the three-dimensional mounting of the semiconductor elements, the production steps thereof can be made simple and the yield thereof can be improved as well, since no heating step based on the heating of the adhesive sheets 12 and 14 is performed. The semiconductor elements can be made even thinner, since the substrate 11 or the like is not warped and the semiconductor elements 13 are not cracked.

### Embodiment 3

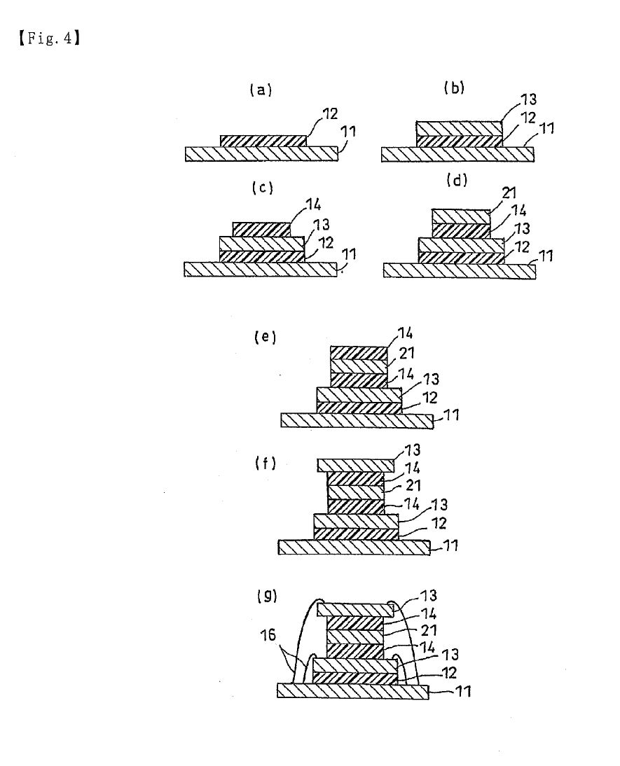

A process for producing a semiconductor device according to embodiment 3 is described with reference to FIG. 4, which are process charts for explaining this process.

The semiconductor device according to the present embodiment is different from the semiconductor device related to the embodiment 2 in that a spacer is inserted between laminated semiconductor elements. More specifically, the present embodiment comprises the step of inserting a spacer between semiconductor elements in such a manner that an adhesive sheet is interposed between the spacer and each of the semiconductor elements, which is different from the embodiment 2.

First, as illustrated in FIGS. 4(a) to 4(c), an adhesive sheet 12, a semiconductor element 13 and an adhesive sheet 14 are successively laminated and pre-set onto a substrate 11 or the like in the same way as in the embodiment 2. Furthermore, on the adhesive sheet 14, a spacer 21, another adhesive sheet 14 and another semiconductor element 13 are successively laminated and pre-set (see FIGS. 4(d) to 4(f)).

Next, as illustrated in FIG. 4(g), a wire bonding step is carried out without performing any heating step, thereby electrically connecting electrode pads of the semiconductor elements 13 to the substrate 11 or the like through bonding wires 16.

Next, a sealing step of sealing the semiconductor elements with a sealing resin is performed to cure the sealing resin and further stick/fix the substrate 11 or the like onto one of the semiconductors element 13 and stick/fix the other semiconductor element 13 onto the spacer 21 through the adhesive sheets 12 and 14. After the sealing step, a post-curing step may be performed. The above-mentioned producing process makes it possible to yield a semiconductor device according to the present embodiment.

The spacer is not limited to any especial kind, and may be a spacer known in the prior art, such a silicon chip or a polyimide film.

### Embodiment 4

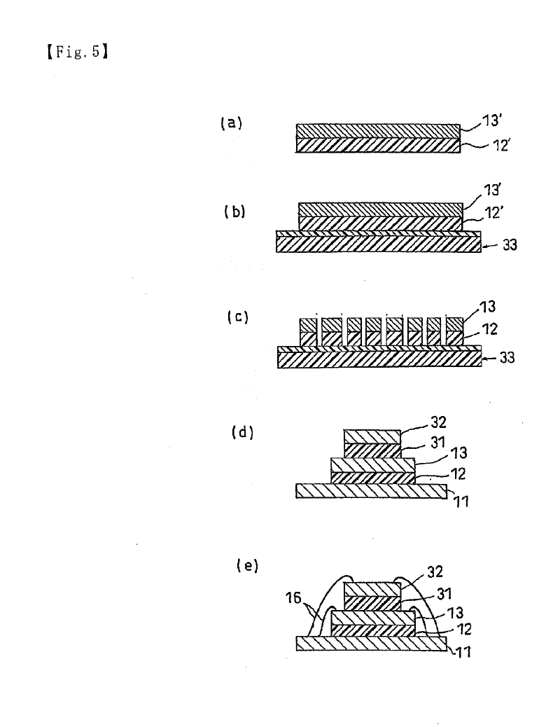

A process for producing a semiconductor device according to embodiment 4 is described with reference to FIG. 5, which are process charts for explaining this process.

First, as illustrated in FIG. 5(a), an adhesive sheet 12′ is stuck onto the rear face of a semiconductor wafer 13′ to form a semiconductor wafer with the adhesive sheet. Next, a dicing tape 33 is pre-set onto the semiconductor wafer 13′ (see FIG. 5(b)). The semiconductor wafer with the adhesive sheet is then diced into chips each having a given size (see FIG. 5(c)). The chips with the adhesive are peeled from the dicing tape 33.

Next, as illustrated in FIG. 5(d), one 13 of the semiconductor elements with an adhesive sheet 12 is pre-set onto a substrate 11 or the like in such a manner that the wire bonding face thereof is directed upwards. A semiconductor element 32, which has a different size from that of the semiconductor element 13 and has an attached adhesive sheet 31, is pre-set onto the semiconductor element 13 in such a manner that the wire bonding face thereof is directed upwards.

Next, as illustrated in FIG. 5(e), a wire bonding step is carried out without performing any heating step, thereby electrically connecting electrode pads of the semiconductor elements 13 and 32 to the substrate 11 or the like through bonding wires 16.

Next, a sealing step of sealing the semiconductor elements with a sealing resin is performed to cure the sealing resin and further to stick/fix the substrate 11 or the like onto the semiconductor 13 and stick/fix the semiconductor element 13 onto the semiconductor element 32 through the adhesive sheet pieces 12 and 31. After the sealing step, a post-curing step may be performed. The above-mentioned producing process makes it possible to yield a semiconductor device according to the present embodiment.

### Embodiment 5

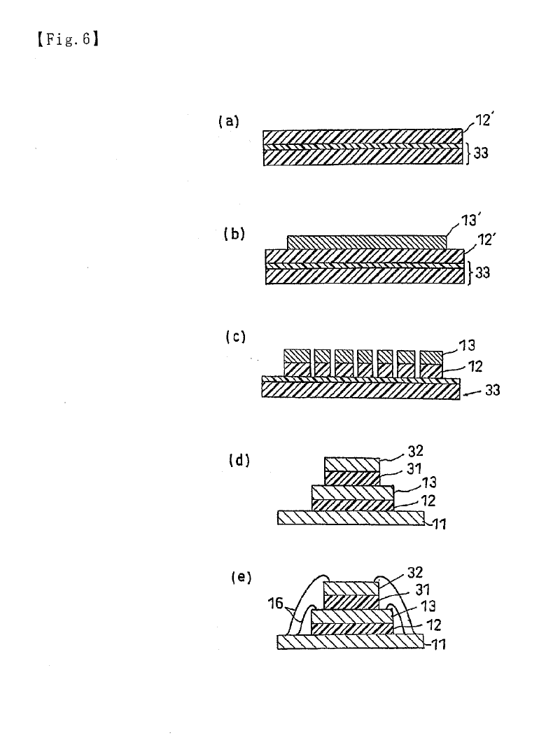

A process for producing a semiconductor device according to Embodiment 5 is described with reference to FIG. 6, which are process charts for explaining this process.

The semiconductor device producing process according to the present embodiment is different from the semiconductor device producing process according to the embodiment 4 in that an adhesive sheet 12′ is laminated onto a dicing tape 33 and subsequently a semiconductor wafer 13′ is laminated onto the adhesive sheet 12′.

First, as illustrated in FIG. 6(a), an adhesive sheet 12′ is laminated onto a dicing tape 33. A semiconductor wafer 13′ is then laminated onto the adhesive sheet 12′ (see FIG. 6(b)). The semiconductor wafer with the adhesive sheet is then diced into chips each having a given size (see FIG. 6(c)). The chips with the adhesive are peeled from the dicing tape 33.

Next, as illustrated in FIG. 6(d), one 13 of the semiconductor elements with an adhesive sheet piece 12 is pre-set onto a substrate 11 or the like in such a manner that the wire bonding face thereof is directed upwards. A semiconductor element 32, which has a different size from that of the semiconductor element 13 and has an attached adhesive sheet 31, is pre-set onto the semiconductor element 13 in such a manner that the wire bonding face thereof is directed upwards. At this time, the sticking/fixing of the semiconductor element 32 is performed to avoid electrode pad portions of the subjacent semiconductor element 13.

Next, as illustrated in FIG. 6(e), a wire bonding step is carried out without performing any heating step, thereby electrically connecting electrode pads of the semiconductor elements 13 and 32 to lands for internal connection in the substrate 11 or the like through bonding wires 16.

Next, a sealing step of sealing the semiconductor elements with a sealing resin is performed to cure the sealing resin and further to stick/fix the substrate 11 or the like onto the semiconductor element 13 and stick/fix the semiconductor element 13 onto the semiconductor element 32 through the adhesive sheet pieces 12 and 31. After the sealing step, a post-curing step may be performed. The above-mentioned producing process makes it possible to yield a semiconductor device according to the present embodiment.

### Embodiment 6

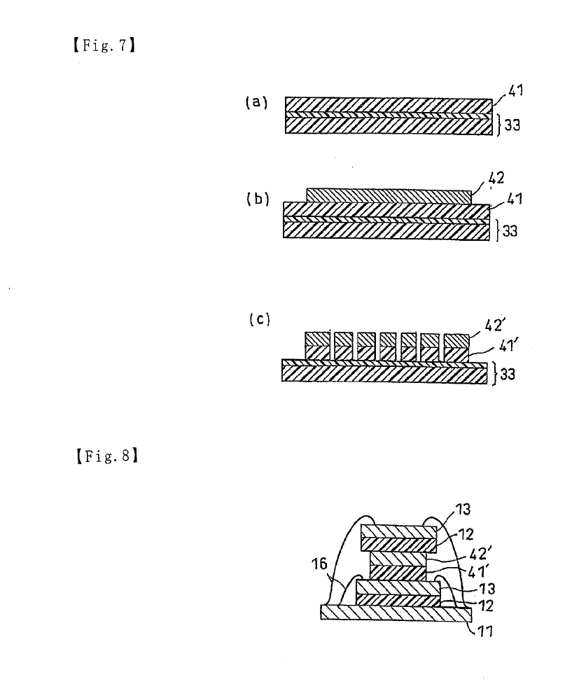

A process for producing a semiconductor device according to Embodiment 6 is described with reference to FIGS. 7 to 8. FIG. 7 is process charts for explaining this process. FIG. 8 is a sectional view, which schematically illustrates a semiconductor device obtained by the semiconductor device producing process according to the present embodiment.

The semiconductor device according to the present embodiment is different from the semiconductor device according to the embodiment 3 in that a core member is used as a spacer.

First, an adhesive sheet 12′ is laminated onto a dicing tape 33 in the same way as in the embodiment 5. A semiconductor wafer 13′ is then laminated onto the adhesive sheet 12′. The semiconductor wafer with the adhesive sheet is then diced into chips each having a given size. The chips with the adhesive are peeled from the dicing tape 33, thereby yielding semiconductor elements 13 to each of which an adhesive sheet piece 12 is attached.

Separately, an adhesive sheet 41 is formed on a dicing tape 33, and then a core member 42 is attached onto the adhesive sheet 41. The resultant is then diced into chips each having a given size. The chips with the adhesive are peeled from the dicing tape 33, thereby yielding core member pieces 42′ which are each in a chip form and each have an attached adhesive sheet piece 41′.

Next, one of the semiconductor elements 13 is pre-set onto a substrate 11 or the like through the adhesive sheet 12 in such a manner that the wire bonding face thereof is directed upwards. Furthermore, one of the core member 42′ is pre-set onto the semiconductor element 13 through the adhesive sheet 41′. Another element out of the semiconductor elements 13 is pre-set onto the core member 42′ through the adhesive sheet 12 in such a manner that the wire bonding face thereof is directed upwards. The above-mentioned producing process makes it possible to yield a semiconductor device according to the present embodiment.

Next, a wire bonding step is carried out without performing any heating step, thereby electrically connecting electrode pads of the semiconductor elements 13 to lands for internal connection in the substrate 11 or the like through bonding wires 16 (see FIG. 8).

Next, a sealing step of sealing the semiconductor elements with a sealing resin is performed to cure the sealing resin and further to stick/fix the substrate 11 or the like onto one of the semiconductors element 13 and stick/fix the other semiconductor element 13 onto the core member piece 42′ through the adhesive sheet 12 and 41′. After the sealing step, a post-curing step may be performed. The above-mentioned producing process makes it possible to yield a semiconductor device according to the present embodiment.

The core member is not limited to any especial kind, and may be a core member known in the prior art. Specific examples of the core member include films (such as polyimide film, polyester film, polyethylene terephthalate film, polyethylene naphthalate film, and polycarbonate film); resin substrates which are reinforced with glass fiber or plastic nonwoven finer; mirror silicon wafers; silicon substrates; and glass substrates.

### Embodiment 7

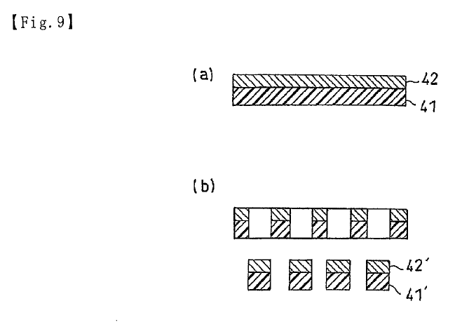

A process for producing a semiconductor device according to Embodiment 7 is described with reference to FIG. 9, which are process charts for explaining this process.

The semiconductor device producing process according to the present embodiment is different from the semiconductor device producing process according to the embodiment 6 in that a core member is made into chips by punching or some other method instead of dicing.

First, semiconductor elements 13 each provided with an adhesive sheet 12 are yielded in the same way as in the embodiment 6. Separately, a core member 42 is attached onto an adhesive sheet 41. The resultant is made into chips each having a given size by punching or some other method. In this way, cores member 42′ each of which is in a chip form and provided with an adhesive sheet 41′ are yielded.

Next, one of the core member pieces 42′ and one of the semiconductor elements 13 are successively laminated on another element out of the semiconductor elements 13 through the adhesive sheet pieces 12 and 41′ and then are pre-set in the same way as that of Embodiment 6.

Furthermore, the resultant is subjected to a wire bonding step, a sealing step and an optional post-curing step, so as to yield a semiconductor device according to the present embodiment.

### (Other Items)

When semiconductor elements are three-dimensional mounted onto any one of the above-mentioned substrates, a buffer coat layer may be formed on the substrate surface on which circuits of the semiconductor elements are formed. The buffer coat layer may be, for example, a silicon nitride film, or a layer made of a heat-resistant resin such as polyimide resin.

The compositions of the adhesive sheets used in the respective stages at the time of the three-dimensional mounting of the semiconductor elements may be the same, but not limited thereto, and may be appropriately varied dependently on the producing conditions or use purposes thereof, or the like.

The laminating method of each of the above-mentioned embodiments is a mere example, and may be appropriately changed if necessary. For example, in the semiconductor device producing process according to the embodiment 2, the semiconductor elements in the second stage and higher stages may be laminated by the laminating method described about the embodiment 3.

About the above-mentioned embodiments, there are described embodiments wherein semiconductor elements are laminated on a substrate or the like and subsequently all the elements are subjected to a wire bonding step at a time. However, the present invention is not limited to the embodiments. For example, a wire bonding step may be performed every time when semiconductor elements are laminated on or over a substrate or the like.

### EXAMPLES

Preferred examples of this invention will be illustratively described in detail hereinafter. However, materials, blend amounts and others that will be described in the Examples do not limit to this invention unless any restrictive description is particularly included. Thus, these are mere explanatory examples. In the examples, the word “part(s)” represent “part(s) by weight”, respectively, unless otherwise specified.

### Example 1

First, the following were mixed with each other: 40 parts of a polymer made mainly from butyl acrylate (PARACRON SN-710, manufactured by Negami Chemical Industrial Co., Ltd.); 37 parts of an epoxy resin (EPICOAT 1003, manufactured by Japan Epoxy Resins Co., Ltd.); 23 parts of a phenol resin (P-180, manufactured by Arakawa Chemical Industries, Ltd.); 3 parts of an isocyanate based crosslinking agent (trade name: CORONATE HX, manufactured by Nippon Polyurethane Industry Co., Ltd.); and 10 parts of a lamellar silicate (trade name: SOMASIF MEE, manufactured by CO-OP Chemical Co., Ltd., average length of long diameters: 3.2 μm, average aspect ratio: 84). The mixture was then dissolved into methyl ethyl ketone, and stirred to prepare an acrylic adhesive composition solution having a concentration of 20% by weight.

This adhesive composition solution was painted onto a releasing-treated film (core material) made of a polyethylene terephthalate film (thickness: 50 μm) subjected to releasing treatment with a silicone, and then the resultant was dried at 120° C. for 3 minutes. In this way, an adhesive sheet according to present Example 1 was produced wherein an adhesive layer of 25 μm thickness was laminated on the releasing-treated film.

### Example 2

The following were mixed with each other: an acrylic copolymer the constituent monomers of which were composed of 70 parts of 2-ethylhexyl acrylate, 25 parts of n-butyl acrylate, and 5 parts of acrylic acid; 3 parts of an isocyanate based crosslinking agent (trade name: CORONATE HX, manufactured by Nippon Polyurethane Industry Co., Ltd.); and 20 parts of a lamellar silicate (trade name: SOMASIF MEE, manufactured by CO-OP Chemical Co., Ltd., average length of long diameters: 3.2 μm, average aspect ratio: 84). The mixture was then dissolved into methyl ethyl ketone, and stirred to prepare an acrylic adhesive composition solution having a concentration of 20% by weight.

Furthermore, in the same way as in Example 1, an adhesive sheet was produced wherein an adhesive layer of 25 μm thickness was laminated on the releasing-treated film.

### Comparative Example 1

In present Comparative Example 1, the same process as in Example 1 was performed except that no lamellar silicate was added at the time of the preparation of the adhesive composition. In this way, an adhesive sheet of present Comparative Example 1 was produced. The thickness of the adhesive layer in the adhesive sheet was set to 25 μm.

### Comparative Example 2

An adhesive sheet according to Comparative Example 2 was formed in the same way as in Comparative Example 1 except that a polymer made mainly of acrylic ester type polymer (PARACRON SN-710, manufactured by Negami Chemical Industrial Co., Ltd.) was used instead of the butyl acrylate used in Comparative Example 1. The thickness of the adhesive layer in the adhesive sheet was set to 25 μm.

### Example 3

In present Example 3, an acrylic adhesive having the same composition as in Example 1 was prepared except that 42 parts of the lamellar silicate was added in the preparation of the acrylic adhesive in Example 1. However, the addition of the 42 parts of the lamellar silicate gave an adhesive sheet wherein the lamellar silicate was worse in compatibility with the organic resin composition than in the adhesive sheets of Examples 1 and 2 so that the silicate was unevenly dispersed.

### Example 4

In present Example 4, the same process as in Example 1 was performed except that 0.1 part of a lamellar silicate (SOMASIF MEE, manufactured by CO-OP Chemical Co., Ltd., average length of long diameters: 3.2 μm, average aspect ratio: 84) was added in the preparation of the acrylic adhesive composition. In this way, an adhesive sheet of the present example was produced. The thickness of the adhesive layer in the adhesive sheet was set to 25 μm.

### Example 5

In present Example 5, the same process as in Example 1 was performed except that 40 part of a lamellar silicate (SOMASIF MEE, manufactured by CO-OP Chemical Co., Ltd., average length of long diameters: 3.2 μm, average aspect ratio: 84) was added in the preparation of the acrylic adhesive composition. In this way, an adhesive sheet of the present example was produced. The thickness of the adhesive layer in the adhesive sheet was set to 25 μm.

### Example 6

In present Example 6, the same process as in Example 1 was performed except that 5 parts of boron nitride (trade name: GSP, manufactured by Tokuyama Corp., average particle diameter: 5 μm) were added instead of the lamellar silicate used in Example 1. In this way, an adhesive sheet according to the present example was produced. The thickness of the adhesive layer in the adhesive sheet was set to 25 μm.

### Example 7

In present Example 7, the same process as in Example 1 was performed except that 0.09 part of a lamellar silicate (SOMASIF MEE, manufactured by CO-OP Chemical Co., Ltd., average length of long diameters: 3.2 μm, average aspect ratio: 84) was added in the preparation of the acrylic adhesive composition. In this way, an adhesive sheet of the present example was produced. The thickness of the adhesive layer in the adhesive sheet was set to 25 μm.

### (Results)

The adhesive sheets of Examples 1, 2 and 4 to 7, and Comparative Examples 1 and 2 were evaluated about each of the tensile storage elasticity, the shearing adhesive force, the dicing property and the moisture absorption reliability thereof in accordance with methods described below. The results are as shown in Table 1.

### [Tensile Storage Elasticity]

The adhesive composition solution used in each of the Examples and the Comparative Examples was painted onto a peel liner subjected to releasing treatment to form an adhesive layer of 100 μm thickness. The adhesive layer was allowed to stand still at 150° C. in an oven for 1 hour, and then a viscoelasticity meter (model name: RSA-II, manufactured by TA Instruments) was used to measure the tensile storage elasticity at 200° C. after the adhesive layer was cured. More specifically, the size of the sample was set to a size 30.0×5.0×0.1 mm in length, width and thickness, respectively. The sample to be measured was set to a film-pull-measurement tool to measure the elasticity at a frequency of 1.0 Hz, a strain of 0.025% and a temperature-raising rate of 10° C./minute in the temperature range of 50 to 250° C.

### [Measurement of Shearing Adhesive Force]

About each of the adhesive sheets of the Examples and Comparative Examples, the shearing force when the sheet was temporarily bonded to a substrate was measured as follows:

First, an aluminum-evaporated wafer was diced to form a chip 2 mm in length, 2 mm in width and 500 μm in thickness. This chip was die-attached to a substrate through each of the adhesive sheets yielded in the Examples and Comparative Examples to form each test piece. The adhesive sheet was peeled from the separator, and then cut into a size 2 mm square. This square was used. The die-attachment was performed by use of a die bonder (SPA-300 manufactured by Shinkawa Ltd.) under a condition that heating was performed at a temperature of 120° C. for 1 second under a load (0.25 MPa). The used substrate was a substrate, TFBDA 16×16 (2216-001A01) (trade name), manufactured by UniMicron Technology Corp. At this time, about the adhesive sheets yielded in the Examples, the sheets were each able to be temporarily bonded to the substrate and the chip without generating any gap in the adhesive face therebetween.

The measurement of the shearing adhesive force was made by fixing each of the test pieces onto a hot plate, the temperature of which was permitted to be controlled, and pushing the die-attached semiconductor element horizontally at a rate of 0.1 mm/second by means of a push pull gauge while heating the semiconductor element at 175° C. The used measuring machine was a machine Model-2252 (trade name) manufactured by AIKOH Engineering Co., Ltd.

### [Dicing Property Evaluation]

A dicing tape (NBD-5170K, manufactured by Nitto Denko Corporation.) was attached to each of the adhesive sheets yielded in the Examples and Comparative Examples at 50° C. The resultant was attached to the rear surface of a wafer (diameter: 6 inches, thickness: 150 μm) at 50° C. Thereafter, a dicer was used to dice the wafer into chips each having a semiconductor element size 5 mm square at a spindle rotation number of 40,000 and a dicing speed of 50 mm/sec. At this time, it was examined whether or not the chips flied and scattered. A case where the chip-flying ratio was 10% or less was estimated as no chip-flying.

### [Wire Bonding Property]

The above-mentioned semiconductor element was die-bonded to a die pad region of a lead frame at 120° C. and 500 gf for 1 second. Thereafter, a 115K-Hz wire bonder (UTC-300BIsuper, manufactured by Shinkawa Ltd.) was used to perform wire bonding through gold wires having a diameter of 25 μm (GMG-25, manufactured by Tanaka Kikinzoku Kogyo K.K.) under conditions described below. Approximately one hour was required for completing the bonding wholly. After the end of the step, the adhesive state of the semiconductor element and the lead frame was checked. As a result, about the adhesive sheets of the Examples, the sheets were each not completely bonded although the thermal history for 1 hour was applied thereto. Thus, a temporarily-bonded state was kept.

First bonding press: 80 g

First bonding ultrasonic strength: 550 mW

First bonding applying time: 10 msec

Second bonding press: 80 g

Second bonding ultrasonic strength: 500 mW

Second bonding applying time: 8 msec

### [Evaluation of Humidity Absorption Reliability]

The above-mentioned semiconductor element was die-bonded to a bismaleimide-triazine resin substrate at 120° C. and 500 gf for 1 second. Thereafter, the resultant was subjected to thermal history at 180° C. for 1 hour. A molding machine (Model-Y-series, manufactured by Towa Japan) was used to mold these members with an epoxy-based sealing resin (trade name: HC-300B6, manufactured by Nitto Denko Corporation.) at 175° C. under conditions that the period for preheating was set to 3 seconds, the period for injection was set to 12 seconds, and the period for curing was set to 120 seconds. Furthermore, the resultant was heated and cured at 175° C. for 5 hours to yield a semiconductor package.

A thermostat was used to subject this semiconductor package to humidity absorbing treatment in an environment of 30° C. temperature and 60% RH humidity for 192 hours. Thereafter, the resultant was charged into an IR reflow machine SAI-2604M (manufactured by Senju Metal Industry Co., Ltd.), and the charging was repeated 3 times. At this time, the package surface peak temperature was adjusted to be set to 260° C. Thereafter, the center of the package was cut, and the cut faces were polished. Thereafter, an optical microscope manufactured by Keyence Corporation was used to observe the cross sections of the package. The package is represented by ◯ when it was recognized that the adhesive sheet was not peeled in the package cross sections, and is represented by x when the adhesive sheet was peeled therein.

TABLE 1

| | | | | | | | Comparative | Comparative |
|---|---|---|---|---|---|---|---|---|
| | Example 1 | Example 2 | Example 4 | Example 5 | Example 6 | Example 7 | Example 1 | Example 2 |
| Tensile storage | 12.7 | 15.2 | 8.7 | 30.5 | 24.7 | 8.5 | 1.9 | 1.4 |
| elasticity of | | | | | | | | |
| adhesive layer at | | | | | | | | |
| 120° C.(MPa) | | | | | | | | |
| Tensile storage | 3.0 | 2.8 | 2.1 | 41.2 | 13.4 | 1.8 | 1.0 | 0.9 |
| elasticity of | | | | | | | | |
| adhesive layer at | | | | | | | | |
| 200° C.(MPa) | | | | | | | | |
| shearing adhesive | 0.65 | 0.57 | 0.52 | 0.35 | 0.79 | 0.48 | 0.16 | 0.05 |
| force(MPa) | | | | | | | | |
| Dicing property | none | none | none | none | none | none | present | present |
| (chip fly) | | | | | | | | |
| Wire bonding | 100% | 100% | 100% | 100% | 100% | 100% | 90% | 0 |
| property(success | | | | | | | | |
| probability) | | | | | | | | |
| humidity absorption | ◯ | ◯ | ◯ | ◯ | ◯ | X | X | X |
| reliability | | | | | | | | |
| (presence or absence | | | | | | | | |
| of peel-off) | | | | | | | | |

As is clear from Table 1, the adhesive sheets of Examples 1, 2 and 4 to 7 of the invention exhibited good shearing adhesive force and dicing property. This demonstrated that the addition of a lamellar clay mineral such as a lamellar silicate or boron nitride makes it possible to restrain a decline in the adhesive property. Moreover, the success probability of the wire bonding was also 100%. Thus, it was understood that the adhesive sheet of each of the Examples did not cause shearing deformation and was excellent in wire bonding property. Additionally, the adhesive sheets of Examples 1, 2 and 4 to 6 exhibited good peelability in the humidity absorption reliability test, and did not cause any peel failure. In other words, it was ascertained from the adhesive sheets of the individual Examples that the use of a lamellar silicate and boron nitride makes it possible to supply a semiconductor package exhibiting high reliability while having an unprecedented heat resistance. On the other hand, the conventional shearing adhesive force of the acrylic resin adhesives, which was shown in Comparative Examples 1 and 2, was insufficient when the adhesives were heated. Thus, at the time of the wire bonding, bonding failures, such as chip-shift, were generated. When the adhesive sheets of Comparative Example 1 and 2 were each used, a peel failure was generated in the humidity absorption reliability test.

1. An adhesive sheet for producing a semiconductor device, which is used when a semiconductor element is caused to adhere onto an adherend and the semiconductor element is wire-bonded, in which a lipophilic lamellar clay mineral is contained.

2. The adhesive sheet for producing a semiconductor device according to claim 1, in which the content of the lamellar clay mineral ranges from 0.1 to 40 parts by weight for 100 parts by weight of an adhesive composition that constitutes the adhesive sheet.

3. The adhesive sheet for producing a semiconductor device according to claim 1, which has a shearing adhesive force of 0.2 to 2 MPa to the adherend under a condition of 175° C. temperature.

4. The adhesive sheet for producing a semiconductor device according to claim 1, which has a tensile storage elasticity of 1×10⁴ Pa or more at 120° C. before the sheet is cured, and has a tensile storage elasticity of 50 MPa or less at 200° C. after the sheet is cured.

5. The adhesive sheet for producing a semiconductor device according to claim 2, wherein the adhesive composition comprises a thermoplastic resin.

6. The adhesive sheet for producing a semiconductor device according to claim 2, wherein the adhesive composition comprises a thermoplastic resin and a thermosetting resin.

7. The adhesive sheet for producing a semiconductor device according to claim 5, wherein the thermoplastic resin is an acrylic resin.

8. The adhesive sheet for producing a semiconductor device according to claim 6, wherein the thermoplastic resin is an acrylic resin.

9. The adhesive sheet for producing a semiconductor device according to claim 6, wherein the thermosetting resin is at least either an epoxy resin or a phenol resin.

10. The adhesive sheet for producing a semiconductor device according to claim 2, in which the adhesive composition comprises an epoxy resin, a phenol resin and an acrylic resin, and the mixed amount of the epoxy resin and the phenol resin is from 10 to 200 parts by weight for 100 parts by weight of the acrylic resin component.

11. The adhesive sheet for producing a semiconductor device according to claim 10, to which a crosslinking agent is added.

12. The adhesive sheet for producing a semiconductor device according to claim 11, in which the added amount of the crosslinking agent is from 0.05 to 7 parts by weight for 100 parts by weight of the acrylic resin.

13. The adhesive sheet for producing a semiconductor device according to claim 1, in which the average length of the long diameters of the lamellar clay mineral ranges from 0.01 to 100 μm.

14. The adhesive sheet for producing a semiconductor device according to claim 1, in which the aspect ratio of the lamellar clay mineral ranges from 20 to 500.

15. The adhesive sheet for producing a semiconductor device according to claim 1, in which the lamellar clay mineral is a lamellar silicate.

16. A method for producing a semiconductor device, comprising:
a temporarily-bonding step of bonding a semiconductor element temporarily onto an adherend with an adhesive sheet for producing the semiconductor device containing a lipophilic lamellar clay mineral interposed therebetween;
a wire bonding step of wire-bonding the semiconductor element;
a sealing step of resin-sealing the semiconductor element with a sealing resin; and
a cutting step of cutting the sealed structure into individual semiconductor elements.

17. The method for producing a semiconductor device according to claim 16, in which the adherend is a substrate, a lead frame, or a semiconductor element.

18. The method for producing a semiconductor device according to claim 16, which comprises the sealing step of sealing the semiconductor element with the sealing resin, and a post-curing step of post-curing the sealing resin,
in which in at least one of the sealing step or the after-curing step, the sealing resin is heated so as to be cured, and further the semiconductor element and the adherend are bonded to each other interposed the adhesive sheet therebetween.

19. The method for producing a semiconductor device according to claim 16, in which the wire bonding step is performed at a temperature ranging from 80 to 250° C.

20. The method for producing a semiconductor device according to claim 16, in which a lamellar silicate is used as the lamellar clay mineral.
